(19) United States
(12) Patent Application Publication
(10) Pub. No.: US 2016/0163738 A1
(43) Pub. Date: Jun. 9, 2016

(54) DISPLAY PANEL MANUFACTURING METHOD AND DISPLAY PANEL

(71) Applicant: JOLED INC., Tokyo (JP)

(72) Inventor: Ichiro SATO, Tokyo (JP)

(73) Assignee: JOLED INC., Tokyo (JP)

(21) Appl. No.: 14/958,000

(22) Filed: Dec. 3, 2015

(30) Foreign Application Priority Data
Dec. 5, 2014 (JP) 2014-247112

(51) Int. Cl. H01L 27/12

(52) U.S. Cl. CPC H01L 27/124; H01L 27/1225; H01L 27/1262

(57) ABSTRACT

A display panel manufacturing method includes: forming connecting wires; forming a common wire which is connected to the connecting wires; forming a first pattern including a preparatory barrier and a channel, by forming a semiconductor film including an oxide semiconductor; forming a second pattern which contacts the channel and does not contact the preparatory barrier; forming a barrier by reducing resistance of the preparatory barrier; and separating the common wire and the barrier.

### CROSS REFERENCE TO RELATED APPLICATION

The present application is based on and claims priority of Japanese Patent Application No. 2014-247112 filed on Dec. 5, 2014. The entire disclosure of the above-identified application, including the specification, drawings and claims is incorporated herein by reference in its entirety.

### FIELD

The present disclosure relates to a display panel manufacturing method of manufacturing a display panel which displays an image using transistors formed in a matrix on a substrate, and to the display panel.

### BACKGROUND

Conventional display panels using liquid crystals or organic electroluminescence (EL) include a matrix of pixels each having red, green, and blue subpixels for displaying a color image (video). Light emission and light transmission of these subpixels are controlled based on a plurality of thin film transistors (TFTs).

These TFTs are arranged in a matrix corresponding to the subpixels and each include, for example, a semiconductor layer formed of low-temperature polysilicon or amorphous silicon (a-Si), a wiring layer, and an insulating layer which isolates the semiconductor layer and the wiring layer.

In manufacturing such a transistor array, layers are stacked, and etching and other processes are performed. There are cases where a trouble of the transistor array is detected using an inspection device or the like in the middle of the manufacturing process. For example, Patent Literature (PTL) 1 describes a method of inspecting a function of a transistor array prior to formation of organic light-emitting diodes (OLEDs). Specifically, PTL 1 discloses a method of detecting open/short defects in driving TFTs in a transistor array prior to mounting OLEDs.

### CITATION LIST

### Patent Literature

[PTL 1] Japanese Unexamined Patent Application Publication No. 2004-347749

### SUMMARY

### Technical Problem

In order to conduct such inspection for operation of a transistor array as that mentioned above, there are cases where a common wire which electrically connects a plurality of data lines or scan lines is provided at an edge of a substrate. Since this common wire is not necessary for displaying an image, an edge section of the substrate is separated to remove the common wire.

Wiring is exposed on a cross-section obtained by the separation, and it has been found that the wiring is corroded from such a portion toward the inside of the substrate.

The present disclosure is based on the above finding and has an object to provide a display panel manufacturing method which allows a barrier to be provided for preventing progress of corrosion toward the inside of a substrate without increasing manufacturing steps much, as well as to provide a display panel with the barrier.

### Solution to Problem

In order to achieve the aforementioned object, a display panel manufacturing method according to an aspect of the present disclosure is a display panel manufacturing method of manufacturing a display panel including a substrate, an array of transistors provided in a display region on the substrate, and a plurality of connecting wires provided in an outer peripheral section around the display region and through which a signal for displaying an image is transmitted to the transistors, the display panel manufacturing method including: forming the plurality of connecting wires; forming a common wire which is electrically connected to the plurality of connecting wires; forming a first pattern by forming a semiconductor film including an oxide semiconductor and then etching the semiconductor film, the first pattern including a channel and a preparatory barrier which becomes a barrier that electrically connects the connecting wires and the common wire and prevents progression of corrosion; forming a second pattern by forming a first insulating film in contact with the channel and then etching the first insulating film, the second pattern remaining in a region corresponding to the channel and not remaining on the preparatory barrier; forming the barrier by reducing resistance of the preparatory barrier, after the forming of a second pattern; and separating the common wire and the barrier.

Furthermore, in order to achieve the aforementioned object, a display panel according to an aspect of the present disclosure is a display panel including: a plurality of transistors provided in a matrix in a display region and each having a channel including an oxide semiconductor; and a plurality of connecting wires provided in an outer peripheral section around the display region and through which a signal for displaying an image is transmitted to the plurality of transistors, wherein the outer peripheral section includes the oxide semiconductor between the plurality of connecting wires, the oxide semiconductor being formed in a layer in which the channel is formed.

### Advantageous Effects

According to the present disclosure, it is possible to prevent corrosion from progressing inward from an edge of a display panel.

### BRIEF DESCRIPTION OF DRAWINGS

These and other objects, advantages and features of the invention will become apparent from the following description thereof taken in conjunction with the accompanying drawings that illustrate a specific embodiment of the present invention.

FIG. 1 is a circuit diagram illustrating a part of a display panel including an edge section thereof according to an embodiment.

FIG. 2 is a cross-sectional view illustrating a structure of a transistor included in a display panel and a structure of an edge section thereof.

FIG. 3 is a plan view illustrating an outer peripheral section around a display region after separation.

FIG. 4 is a cross-sectional view illustrating a step of a first patterning process.

FIG. 5 is a cross-sectional view illustrating a resultant first pattern.

FIG. 6 is a cross-sectional view illustrating a resultant second pattern.

FIG. 7 is a cross-sectional view illustrating a resultant third pattern.

FIG. 8 is a cross-sectional view illustrating a step of a barrier forming process.

FIG. 9 is a cross-sectional view illustrating a resultant barrier.

FIG. 10 is a cross-sectional view illustrating a state where a second insulating layer has been formed.

FIG. 11 is a cross-sectional view illustrating a state where a second insulating layer has a contact hole.

FIG. 12 is a cross-sectional view illustrating a state where a connecting wire 120 has been formed.

FIG. 13 is a cross-sectional view illustrating a state where a third insulating layer has been formed.

FIG. 14 is a plan view illustrating a cut substrate together with a circuit diagram.

FIG. 15 is a circuit diagram illustrating a part of a display panel including an edge section thereof according to an embodiment.

FIG. 16 is a cross-sectional view illustrating a structure of an edge section of a substrate.

FIG. 17 is a cross-sectional view illustrating a resultant pattern.

FIG. 18 is a cross-sectional view illustrating a step of forming a barrier and a resistor.

FIG. 19 is a cross-sectional view illustrating a state in which a substrate has been cut.

### DESCRIPTION OF EMBODIMENTS

Next, embodiments of the display panel manufacturing method according to the present disclosure are described with reference to the Drawings. Note that the following embodiments are mere examples of the display panel manufacturing method and the display panel according to the present disclosure. As such, the scope of the present disclosure is defined by the recitations in the Claims, with reference to the following embodiments, and is not limited to only the following embodiments. Therefore, among the structural elements in the following embodiments, structural elements not recited in any one of the independent claims defining the most generic part of the inventive concept are described as preferred structural elements, and are not absolutely necessary to achieve the object of the present disclosure.

Note that the respective figures are schematic diagrams and are not necessarily precise illustrations.

Hereinafter, the display panel manufacturing method and the display panel according to the embodiments are described with reference to the Drawings.

### Embodiment 1

### Structure of Display Panel

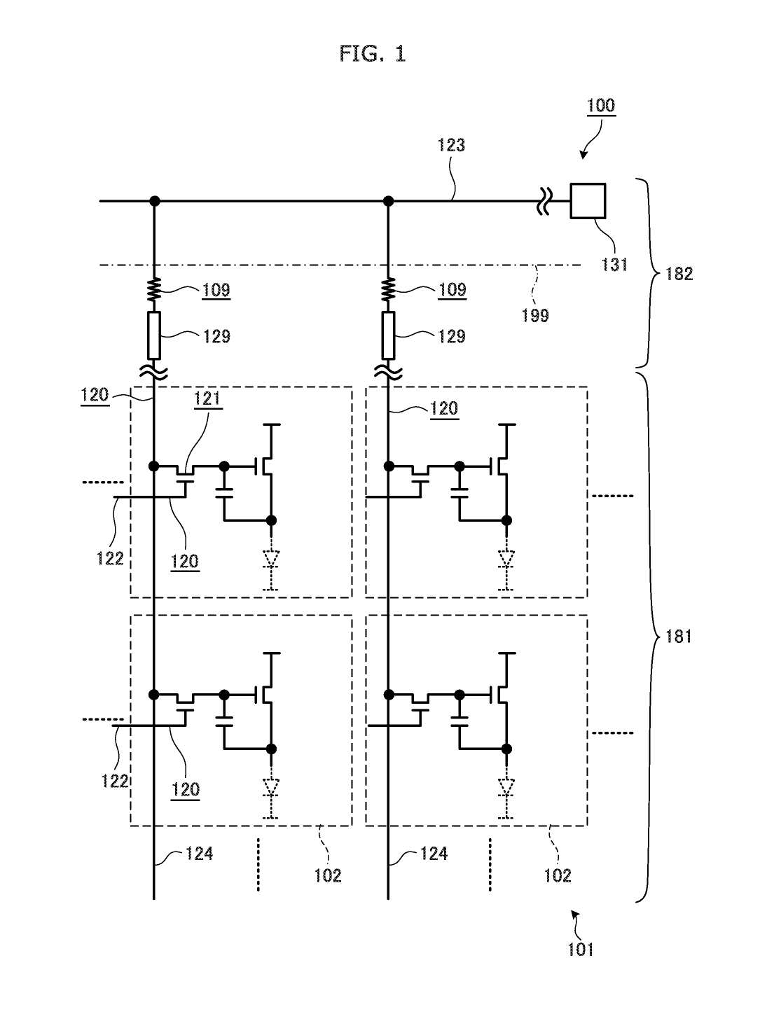

FIG. 1 is a circuit diagram illustrating a part of a display panel including an edge section thereof according to an embodiment.

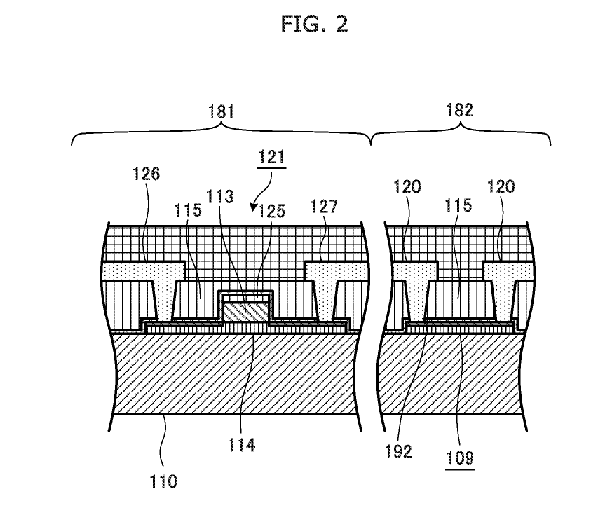

FIG. 2 is a cross-sectional view illustrating a structure of a transistor included in a display panel and a structure of an edge section thereof.

As illustrated in these figures, a display panel 100 includes: a transistor array 101 provided in a display region 181; and a plurality of connecting wires 120, namely, scan lines 122 and data lines 124, which extend from the display region 181 to an outer peripheral section 182 around the display region 181 and through which a signal for displaying an image is transmitted to a transistor 121. In the present embodiment, the display panel 100 is an organic EL display panel 100 including an OLED as a light-emitting element.

The display region 181 serving as a region in which the display panel 100 can display an image and the like nearly matches a region covered by the transistor array 101. The outer peripheral section 182 around the display region 181 is an edge section of the display panel 100.

[Display Region]

As illustrated in FIG. 1, the transistor array 101 is formed of thin film transistors (TFTs) arranged in a matrix. FIG. 1 illustrates a circuit of the transistor array 101 on which an open-short inspection or the like test has not yet been conducted for the connecting wires 120.

The transistor array 101 includes more than one transistor 121 per subpixel 102, and further includes, as the connecting wires 120, the scan lines 122 and the data lines 124 each of which bridges a plurality of subpixels 102.

As illustrated in FIG. 2, the transistor 121 is a transistor formed into a thin film shape on a substrate 110, and includes a gate electrode 125, a source electrode 126, a drain electrode 127, a first insulating layer 113, a channel 114, and a second insulating layer 115.

A selection transistor which is one of transistors 121 is, for example, a thin film transistor having the gate electrode 125 connected to the scan line 122 and the source electrode 126 connected to the data line 124, and is a transistor for selecting whether or not to supply a capacitor with an image signal which is transmitted through the data line 124, based on a scan signal which is transmitted through the scan line 122. The transistor 121 having other functions is provided in the subpixel.

The substrate 110 is a plate-shaped member which not only serves as a base for the transistor 121, but also serves as a base for the entire display panel 100. The material of the substrate 110 is not particularly limited so long as the material of the substrate 110 has insulating properties, and may be formed, for example, from a glass material such as quartz glass, alkali-free grass, or high heat resistant glass, or from a resin material such as polyethylene, polypropylene, or polyimide. The substrate 110 may be a flexible substrate, other than a rigid substrate having relatively high rigidity.

The channel 114 is a portion having a predetermined shape formed on the substrate 110 from an oxide semiconductor (for example, an amorphous oxide semiconductor). In the present embodiment, a transparent amorphous oxide semiconductor (TAOS) is used for the material of the channel 114, and a metal element of the channel 114 is indium (In), tungsten (W), gallium (Ga), zinc (Zn), or the like.

The first insulating layer 113 is what is called a gate insulating layer which is disposed between the gate electrode 125 and the channel 114 as a member which insulates the gate electrode 125 and the channel 114. The first insulating layer 113 is not particularly limited so long as the first insulating layer 113 is formed from an electrically insulating material; the first insulating layer 113 is, for example, a single-layer film formed of a silicon oxide film, a silicon nitride film, a silicon oxynitride film, an aluminum oxide film, a tantalum oxide film, a hafnium oxide film, or the like, or a laminated film formed by stacking two or more layers using these films.

The gate electrode 125 is an electrode having a single-layered or multi-layered structure which includes an electrically conductive film formed from an electrically conductive material, and is formed into a predetermined shape above the substrate 110. The material of the gate electrode 125 is not specifically limited and may be, for example, a metal, or an alloy of two or more types of metal (for example, molybdenum-tungsten), an electrically conductive metal oxide such as indium tin oxide (ITO), aluminum-doped zinc oxide (AZO), or gallium-doped zinc oxide (GZO), or an electrically conductive polymeric material such as polythiophene or polyacetylene.

The gate electrode 125 is included in a third pattern 203, and not only the gate electrode 125 but also wiring and other components may be provided in the same layer above the substrate 110.

The second insulating layer 115 is an interlayer insulating layer which is disposed above the substrate 110 so as to cover the channel 114, the first insulating layer 113, and the gate electrode 125 (the third pattern), and expands in the form of a layer over the entire substrate 110.

The second insulating layer 115 is not particularly limited so long as the second insulating layer 115 is formed from an electrically insulating material; the second insulating layer 115 is, for example, a single-layer film formed of a silicon oxide film, a silicon nitride film, a silicon oxynitride film, an aluminum oxide film, or the like, or a laminated film including these films.

In the present embodiment, there is a layer between the third pattern 203 and the second insulating layer 115. Said layer will be described later.

Furthermore, the second insulating layer 115 has contact holes 118 which penetrate a part of the second insulating layer 115. The channel 114 is connected to the source electrode 126 and the drain electrode 127 through the contact holes 118 of the second insulating layer 115.

The source 126 and the drain electrode 127 are formed above the second insulating layer 115. Specifically, the source electrode 126 and the drain electrode 127 are disposed above the second insulating layer 115, facing each other at a distance in a direction parallel to the substrate 110 (a substrate horizontal direction), and are connected to the channel 114 through the contact holes formed in the second insulting layer 115.

The source electrode 126 and the drain electrode 127 are not particularly limited so long as the source electrode 126 and the drain electrode 127 are formed from an electrically conductive material; the electrically conductive material is, for example, aluminum, tantalum, molybdenum, tungsten, silver, copper, titanium, or chromium. Each of the source electrode 126 and the drain electrode 127 may be a single-layered electrode, or may alternatively be a multi-layered electrode.

As illustrated in FIG. 1, the scan line 122 which is one of the connecting wires 120 is a wire connected to the gate electrode 125 of the transistor 121 and through which a scan signal for displaying an image is transmitted. As a result of the scan line 122 being given the scan signal, the source electrode 126 and the drain electrode 127 of the transistor 121 are placed in a conducting state, that is, the transistor 121 is placed in the ON state. The scan line 122 is connected to the gate electrode 125 of the transistor 121. Two or more scan lines 122, are arranged side by side so as to cross the data lines 124 and extend from the display region 181 to the outer peripheral section 182.

The data line 124 which is one of the connecting wires 120 is a wire connected to each of the source electrodes 126 of the transistors 121 arranged in a line and through which an image signal is transmitted. Two or more data lines 124 are arranged so as to cross the scan lines 122 and extend from one end to another end of the transistor array 101 and further extend from the display region 181 to the outer peripheral section 182.

[Outer Peripheral Section Around Display Region]

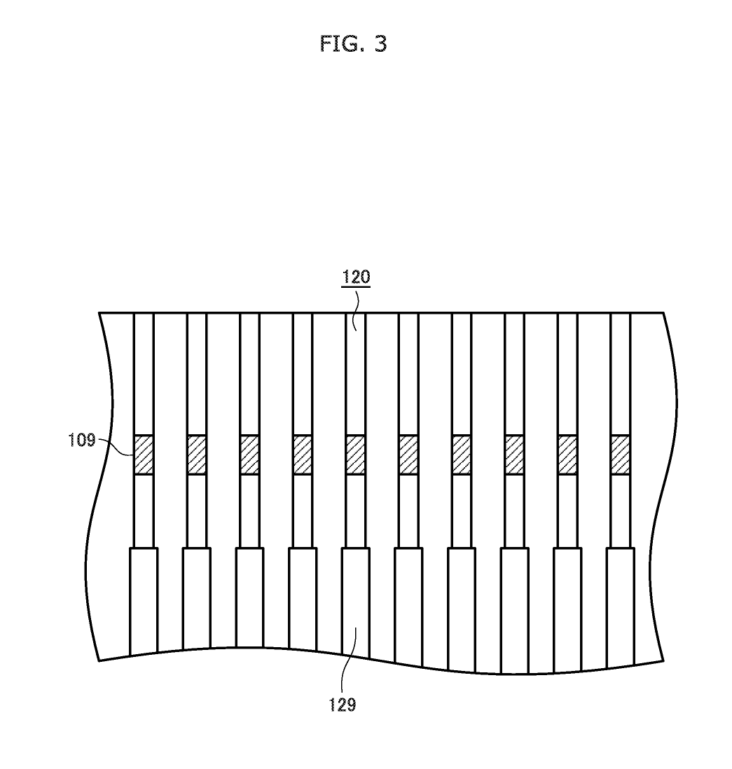

FIG. 3 is a plan view illustrating an outer peripheral section around a display region after separation. Note that the shaded areas in this figure do not indicate a cross section, but indicate portions made from a different material.

As illustrated in this figure, the outer peripheral section 182 around the display region 181 is an area which extends in a direction crossing an edge of the substrate 110 and in which the connecting wires 120 arranged along the edge of the substrate 110 are located. Furthermore, in the outer peripheral section 182, a barrier 109 is provided which is interposed in each of the connecting wires 120.

During manufacture of the display panel 100, the outer peripheral section 182 includes a common wire 123 (see FIG. 1). In the present embodiment, a mounting terminal unit 129 is provided in each of the connecting wires 120 as a part of the connecting wire 120. After inspection of the display panel 100 is completed, the substrate 110 is cut at a separation line 199 (see FIG. 1), resulting in the common wire 123 being removed.

The barrier 109 is a portion disposed in the outer peripheral section 182, between the connecting wires 120 arranged side by side in the same line or between the connecting wires 120 and the common wire 123, and this portion electrically connects such connecting wires 120 or such connecting wires 120 and common wire 123. Even if the connecting wire 120 made from a metal is corroded from an edge of the substrate 110, the barrier 109 servers as a blockade that prevents the corrosion from progressing to the display region 181. The material of the barrier 109 is a semiconductor of the same kind as the oxide semiconductor included in the channel 114, with a reduced resistance; that is, the barrier 109 is formed by reducing the resistance of the oxide semiconductor formed in the same layer as the channel 114.

The reduction in resistance herein indicates changing at least part of a semiconductor into an electrical conductor. Specifically, in the present embodiment, the reduction in resistance means changing a preparatory barrier 191 made from a semiconductor, into the barrier 109 having a sheet resistance in the range from 10 ohms per square to 1,000 ohms per square. A way to reduce the resistance will be described later.

In the present embodiment, the barrier 109 is positioned close to the edge of the substrate 110 relative to the mounting terminal unit 129. With this, the mounting terminal unit 129 is protected from corrosion that originates from the corrosion at a cross section of the cut substrate 110.

The common wire 123 is electrically connected to the plurality of connecting wires 120 and, for example, is connected to an electrostatic discharge (ESD) element, which is referred to as a short-circuit bar or the like, provided in the outer peripheral section 182 in order to protect the transistor 121 from static electricity generated during the manufacture of the display panel 100. Furthermore, the common wire 123 is also used to apply a predetermined voltage, signal, or the like collectively to the respective gate electrodes 125, source electrodes 126, and drain electrodes 127 of the plurality of transistors 121 when various tests are conducted on the display panel 100 which is being manufactured. In FIG. 1, a pad 131 is illustrated which is connected to an end of the common wire 123, for applying a voltage or signal to the common wire 123.

Note that more than one common wire 123 is provided above the substrate 110 and includes those connected to the scan line 122 and those connected to the data line 124.

There are cases where the common wire 123 and the connecting wire 120 are integrally formed, the boundary of which is unclear. In the description herein, the wire present in the area which is removed by cutting the substrate 110 is referred to as the common wire 123.

The mounting terminal unit 129 is a part of the connecting wire 120 and is a terminal for mounting a flexible wire (for example, chip on film (COF)) for transmitting an image signal or a scan signal from outside the display panel 100, for example, a control substrate (for example, a timing controller (T-CON)), to the transistor array 101. The mounting terminal unit 129 is provided in the outer peripheral section 182, with a part exposed on a surface thereof.

[Manufacturing Process of Display Panel]

Next, a manufacturing process of the display panel 100 is described with reference to the Drawings.

First Patterning Process

FIG. 4 is a cross-sectional view illustrating a step of a first patterning process.

As illustrated in this figure, a semiconductor film 119 made from an oxide semiconductor for forming the channel 114 and the preparatory barrier 191 is formed above the substrate 110 so as to expand over the entire substrate 110. In the present embodiment, a TAOS film is formed as the semiconductor film 119 by sputtering or the like method.

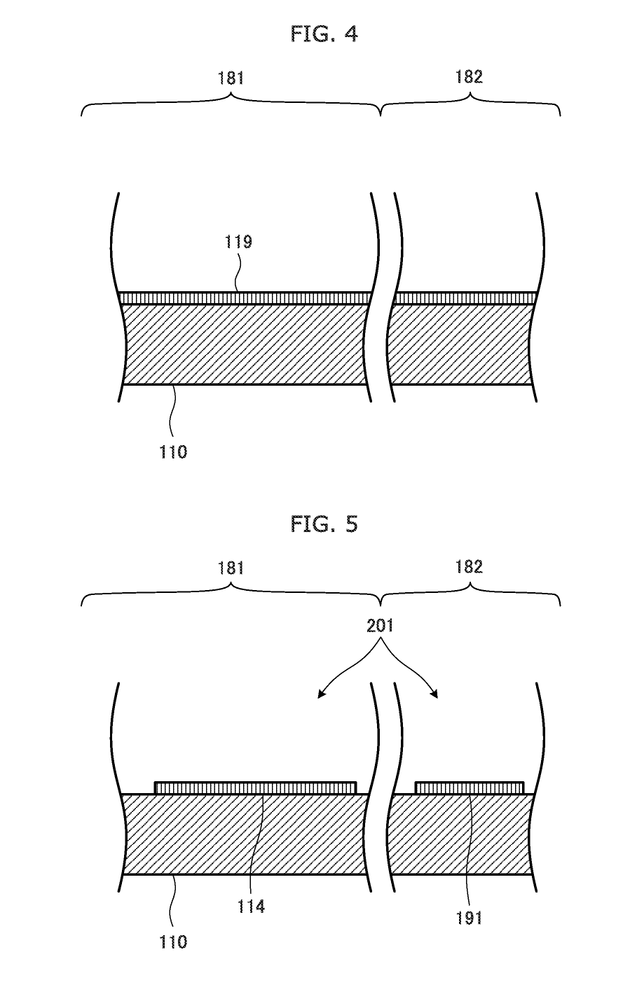

FIG. 5 is a cross-sectional view illustrating a resultant first pattern.

Next, photoresist is formed in a pattern on a surface of the semiconductor film 119 by photolithography or the like method. This photoresist pattern is the same pattern as a first pattern 201 which is to remain in the following etching step.

Next, a portion of the semiconductor film 119 on which the photoresist has not been formed is etched by wet etching or the like method.

Next, the photoresist is removed to allow etching on the semiconductor film 119 to form a first pattern 201 including the channel 114 and the preparatory barrier 191 which becomes the barrier 109 in the later process.

Note that an undercoat may be formed beforehand on the surface of the substrate 110 when the semiconductor film 119 is formed.

Second Patterning Process

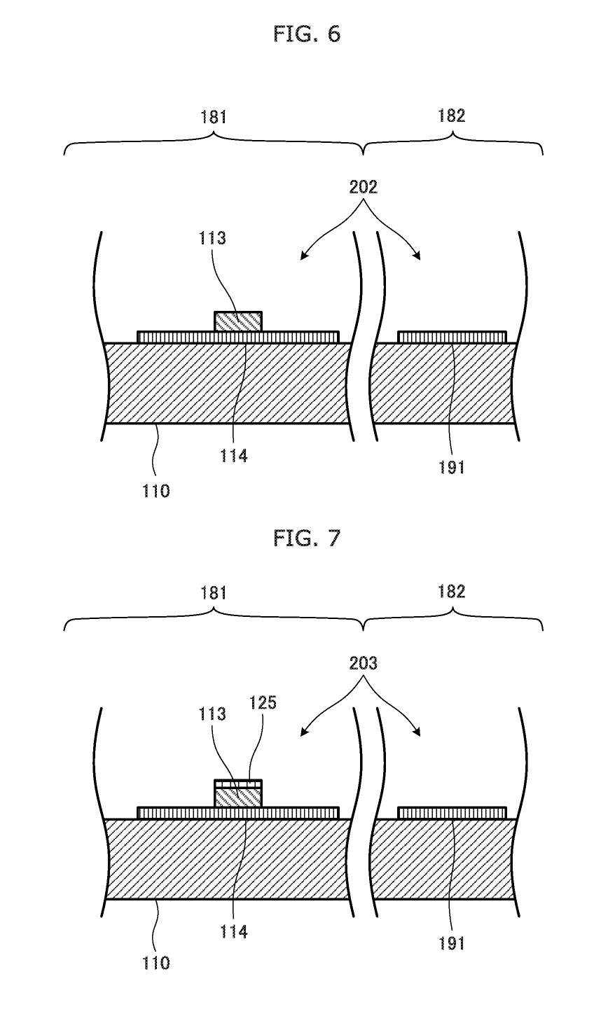

FIG. 6 is a cross-sectional view illustrating a resultant second pattern.

First, a first insulating film is formed over the entire substrate 110 in contact with the first pattern 201. The way to form the first insulating film is not particularly limited and can, for example, be chemical vapor deposition (CVD) or the like method.

Next, a second pattern 202 including the first insulating layer 113 is formed by etching. The first insulating layer 113 remains in a region corresponding to the channel 114 and does not remain on the preparatory barrier 191. The second patterning process is a step of forming the first insulating layer 113 (what is called a gate insulating layer).

Third Patterning Process

FIG. 7 is a cross-sectional view illustrating a resultant third pattern.

First, an electrically conductive film is formed on the entire top surface of the substrate 110 by sputtering or the like method. The electrically conductive film may have, for example, a multi-layered structure including copper and molybdenum.

Next, photoresist is formed in a pattern on a surface of the electrically conductive film by photolithography or the like method. This photoresist pattern is the same pattern as the third pattern 203 which is to remain in the following etching step.

Next, a portion of the electrically conductive film on which the photoresist has not been formed is etched by wet etching or the like method.

Next, the photoresist is removed to form the third pattern which includes the gate electrode 125 of the transistor 121.

Note that the third pattern 203 may include the scan line 122 which is the connecting wire 120 that is connected to the gate electrode 125, and other components such as the common wire 123 and one of the electrodes of the capacitor. In this case, the third patterning process is a part of or the whole connecting wire forming process and a part of or the whole common wire forming process.

Barrier Forming Process

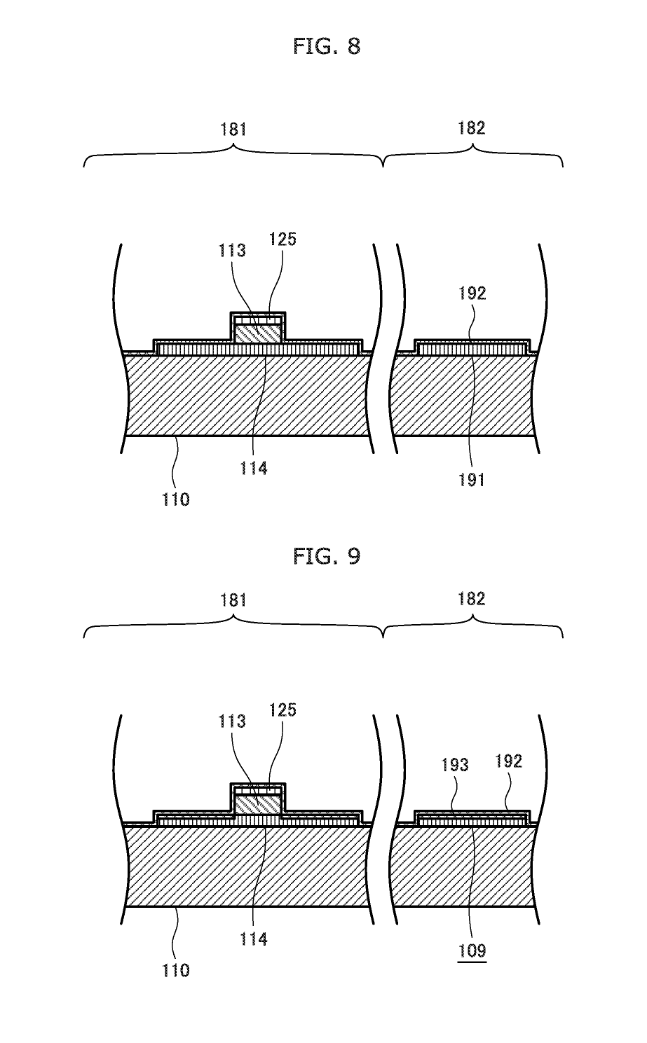

FIG. 8 is a cross-sectional view illustrating a step of a barrier forming process.

FIG. 9 is a cross-sectional view illustrating a resultant barrier.

First, as illustrated in FIG. 8, a resistance-reduction promoting film 192 which contains a metal is formed so as to expand over the entire substrate 110. The resistance-reduction promoting film 192 contains a metal that reacts with oxygen at relatively low temperature. Examples of the metal that reacts with oxygen at relatively low temperature include aluminum (Al), titanium (Ti), and indium (In), and may also be boron (B), gallium (Ga), silicon (Si), germanium (Ge), tin (Sn), and lead (Pb). Furthermore, the resistance-reduction promoting film 192 may contain two or more metals among the above-listed metals. The resistance-reduction promoting film 192 desirably exists in a stable state as an oxide after reacting with oxygen. In this case, the metal contained in the resistance-reduction promoting film 192 is desirably aluminum (AL) and may be titanium (Ti), for example. The way to form the resistance-reduction promoting film 192 is not particularly limited and can, for example, be sputtering or the like method. It is sufficient that the resistance-reduction promoting film 192 has such a thickness that the resistance of the preparatory barrier 191 made from an oxide semiconductor can be reduced to turn the preparatory barrier 191 into the barrier 109. Specifically, when the entire resistance-reduction promoting film 192 is formed from a metal, the thickness of the resistance-reduction promoting film 192 is desirably set to a value selected from the range of 10% to 40% of the thickness of the preparatory barrier 191. This is because the resistance would not be able to be sufficiently reduced if the thickness is less than 10%, and it would be hard to remove the electrical conductivity of the resistance-reduction promoting film 192 even in the next step if the thickness is greater than 40%.

Next, the entire substrate 110 over which the resistance-reduction promoting film 192 has been formed is thermally treated. This thermal treatment is what is called annealing, and is performed by maintaining the substrate 110 at a temperature selected from the range of 100 C.° to 400 C.°. Furthermore, when the thermal treatment is performed, the substrate 110 may be held within a vacuum or may be held in a gas atmosphere containing oxygen. Furthermore, plasma may be generated during the thermal treatment.

Through this process, the resistance of the preparatory barrier 191 is reduced, resulting in the barrier 109. This reduction in resistance is presumed to represent that a part of the preparatory barrier 191 which is in contact with the resistance-reduction promoting film 192 is turned into an electrical conductor. In short, the preparatory barrier 191 including an electrical conductor 193 becomes the barrier 109. Specifically, it is presumed that part of oxygen in a surface area of the preparatory barrier 191 made from the oxide semiconductor leaks out, a metal enters the surface area, and so on, causing a defect in the semiconductor, which turns into an electrical conductor.

Meanwhile, even when the thermal treatment is performed, the channel 114 and the resistance-reduction promoting film 192 do not come into direct contact with each other, between which the first insulating layer 113 is provided, meaning that the channel 114 do not lose the function thereof.

Note that it is also possible to perform the thermal treatment upon forming the resistance-reduction promoting film 192, for example, by forming the resistance-reduction promoting film 192 above the substrate 110 maintained at a temperature of about 100 C.°.

Second Insulating Layer Forming Process

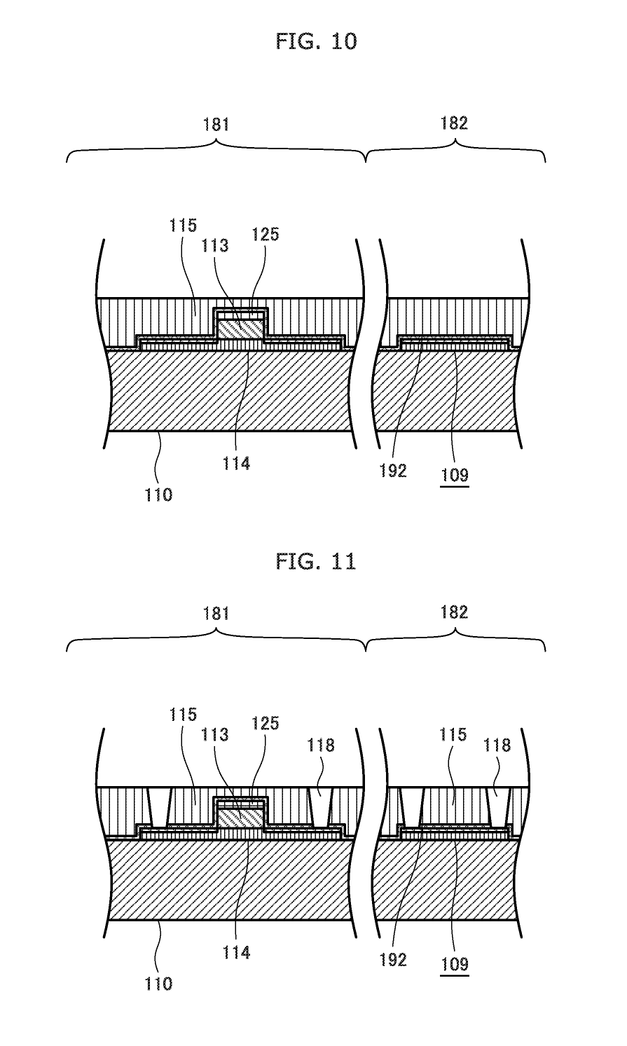

FIG. 10 is a cross-sectional view illustrating a state where a second insulating layer is formed.

A second insulating layer forming process is a process of forming the second insulating layer 115 in the form of a layer which covers the resistance-reduction promoting film 192 that has become an insulator through the thermal treatment. The way to form the second insulating layer 115 is not particularly limited as is the case with the way to form the first insulating layer 113.

Connecting Wire Forming Process and Common Wire Forming Process

The following describes formation of the connecting wire 120 which is electrically connected to the barrier 109.

FIG. 11 is a cross-sectional view illustrating a state where a second insulating layer has a contact hole.

In the present embodiment, first, the contact hole 118 is formed. The contract hole 118 penetrates a single layer or a multi-layer in the thickness direction thereof, for connecting patterns to each other, or a pattern and a channel or the like, which are provided on different layers. In the present embodiment, the contact hole 118 can, for example, be a contact hole that penetrates the second insulating layer 115 in the thickness direction thereof, further penetrates the resistance-reduction promoting film 192 in the thickness direction thereof, and reaches the barrier 109, or be a through-hole that penetrates the second insulating layer 115 and the first insulating layer 113 in the thickness direction thereof and reaches the first pattern 201.

In order to form the contact hole 118, photolithography or the like is used, as in the case of forming the first pattern 201, to form, on a surface of the second insulating layer 115, photoresist in a pattern having a hole at a position in which the contact hole 118 is to be provided, resulting in the contact hole 118 by dry etching or the like method.

In this way, the contact hole 118 which penetrates the second insulating layer 115 and the resistance-reduction promoting film 192 in the thickness direction thereof and reaches the barrier 109 is formed as illustrated in FIG. 11.

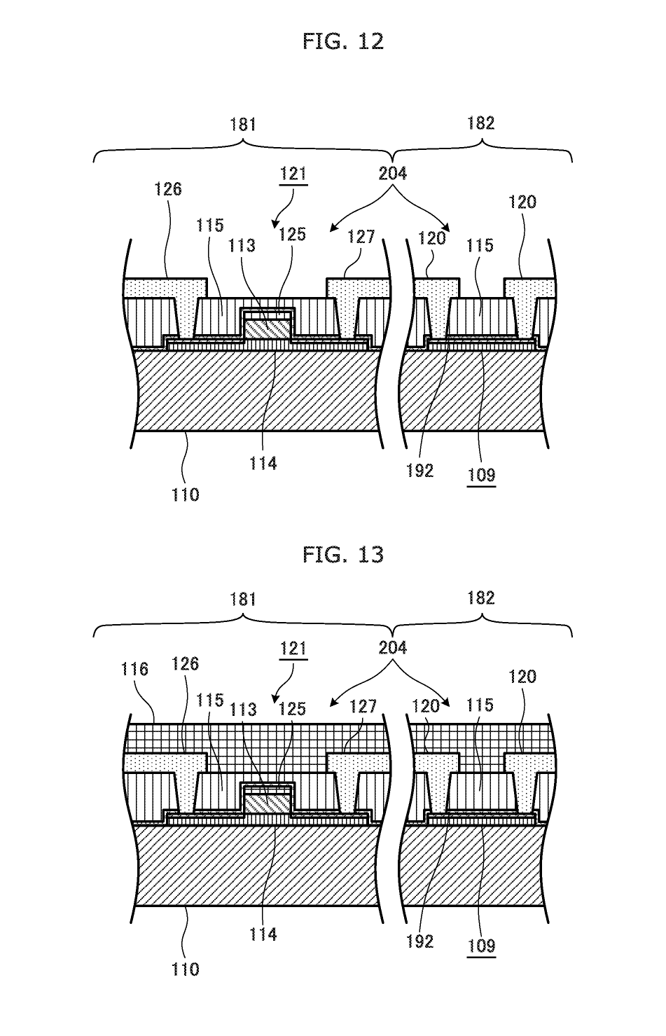

FIG. 12 is a cross-sectional view illustrating a state where the connecting wire 120 has been formed.

In the present embodiment, a fourth pattern 204 including the source electrode 126 and the drain electrode 127 of the transistor 121 is formed to form the connecting wire 120. Note that the fourth pattern 204 may include other wires (for example, the common wire 123).

A way to form the fourth pattern 204 includes forming an electrically conductive film over the entire surface of the second insulating layer 115 by sputtering or the like method as in the case of forming the third pattern 203. As a result, the electrically conductive film is formed on an inner peripheral surface of the contact hole as well, meaning that part of the barrier 109 and the electrically conductive film are in contact with each other.

Next, photoresist is formed in a pattern on a surface of the electrically conductive film by photolithography or the like method. Next, an unnecessary portion of the electrically conductive film is etched by wet etching or the like method. The fourth pattern 204 is formed in this way.

Note that the connecting wire 120 and the common wire 123 may exist in the same layer or may alternatively exist in different layers. Furthermore, the connecting wire 120 and a part of the common wire 123 may exist in different layers. Thus, the connecting wire forming process and the common wire forming process may be performed in a single process, or may be performed separately, or may be performed across more than one process.

Third Insulating Layer Forming Process

FIG. 13 is a cross-sectional view illustrating a state where a third insulating layer has been formed.

A third insulating layer forming process is a process of forming an insulating layer which is called a protective film. The way to form the third insulating layer 116 is not particularly limited as is the case with the way to form the first insulating layer 113.

Separation Process

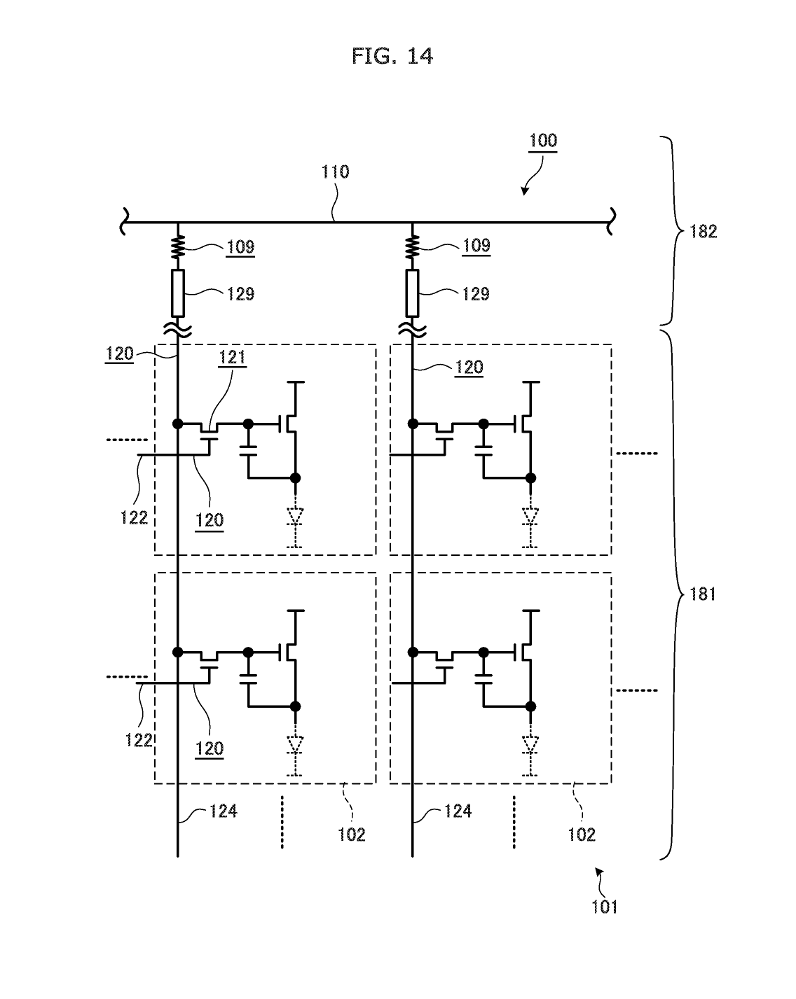

FIG. 14 is a plan view illustrating a cut substrate together with a circuit diagram.

Cutting or separating means a process of removing a part of an edge section of substrate 110 by splitting the wires, the insulating layer, and the like, together with the substrate 110, along a predetermined separation line as illustrated in this figure. The separation line for such cutting or separating is provided between the common wire 123 and the barrier 109. This makes it possible to leave the barrier 109 near the edge of the cut substrate 110.

Although a specific separation method is not particularly limited, examples thereof include making a linear scratch with a laser or a blade and splitting the substrate 110 at the scratched part by bending the edge of the substrate 110.

According to the above-described display panel manufacturing method and display panel, even when corrosion occurs from an end of the connecting wire 120 exposed on the cross-section of the cut substrate 110 after cut, corrosion progressing toward the inside of the substrate 110 along the connecting wire 120 can be inhibited by the barrier 109. Moreover, it is possible to improve the efficiency of producing the display panel 100 without adding a process only for forming the barrier 109 because the barrier 109 can be formed using a semiconductor for the channel 114 of the transistor 121, in the same process for improving the performance of the transistor 121.

### Embodiment 2

Subsequently, Embodiment 2 of the present disclosure is described. Parts having the same action, function, shape, etc., as those in Embodiment 1 are denoted by the same numerals and description thereof may be omitted. The following description will focus on differences from Embodiment 1.

[Structure of Display Panel]

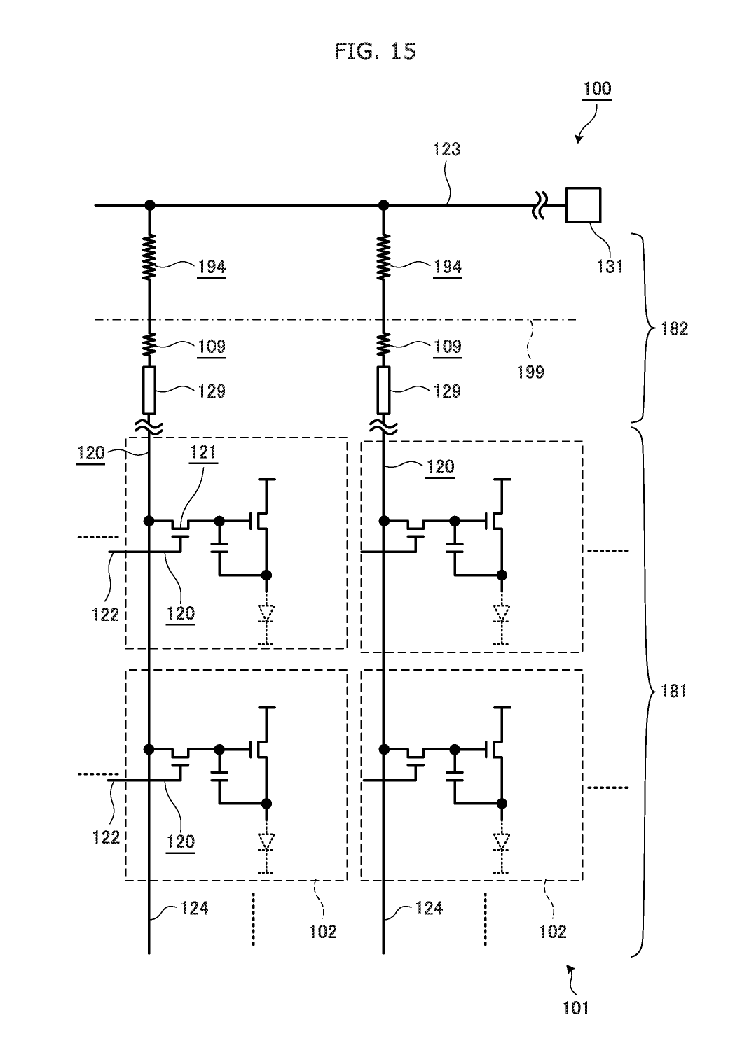

FIG. 15 is a circuit diagram illustrating a part of a display panel including an edge section thereof according to an embodiment.

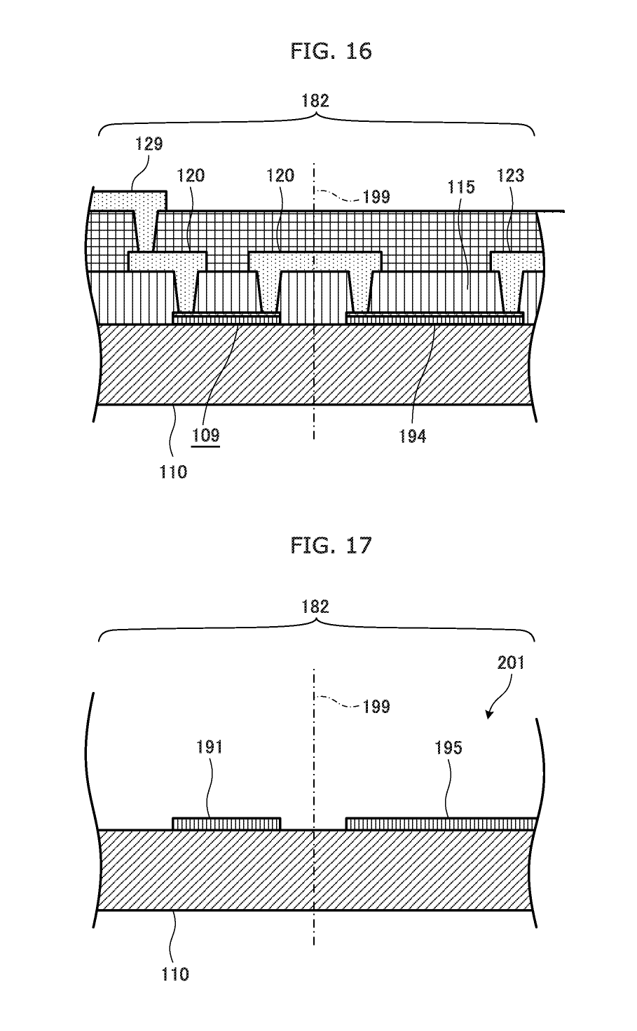

FIG. 16 is a cross-sectional view illustrating a structure of an edge section of a substrate.

As illustrated in these figures, the display panel 100 includes the plurality of connecting wires 120 that reach the outer peripheral section 182 around the display region 181. In the display panel 100 according to the present embodiment, each of the connecting wires 120 arranged side by side includes the barrier 109 and a resistor 194 close to an edge of the substrate 110 relative to the barrier 109.

The resistor 194 electrically connects each of the connecting wires 120 and the common wire 123 with a high resistance (a sheet resistance higher than that of the connecting wire 120 per unit area, for example, a sheet resistance in the range from 10 ohms per square to 1,000 ohms per square like the sheet resistance of the barrier 109).

The length of the resistor 194 is set to a length greater than the length of the barrier 109. This is because when an inspection is conducted using the connecting wires 120 connected to the common wire 123 and any of the connecting wires 120 has a defect, the resistor 194 provides resistance required to distinguish the connecting wire 120 that has a defect, from the connecting wire 120 adjacent thereto.

First Patterning Process

FIG. 17 is a cross-sectional view illustrating a resultant first pattern.

As illustrated in this figure, the first pattern 201 includes a preparatory resistor 195 close to an edge of the substrate 110 (on the right side of this figure relative to the preparatory barrier 191 in the present embodiment.

The way to form the first pattern 201 is the same or similar to that of Embodiment 1.

Second Patterning Process

In the present embodiment, the second pattern 202 is a pattern in which the first insulating layer 113 does not remain on the preparatory resistor 195 either. Accordingly, the state after the second patterning process is just as that illustrated in FIG. 17.

Barrier Forming Process

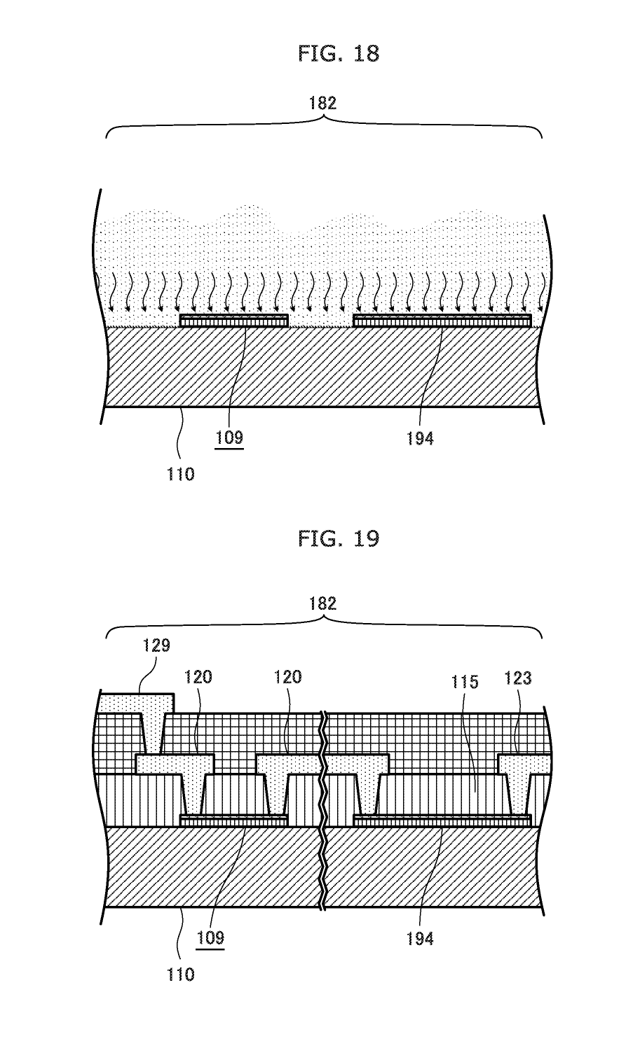

FIG. 18 is a cross-sectional view illustrating a step of forming a barrier and a resistor.

In the present embodiment, the resistance-reduction promoting film 192 is not formed, and plasma is emitted directly to the preparatory barrier 191 and the preparatory resistor 195 to reduce the resistance of the preparatory barrier 191 and the preparatory resistor 195 and form the barrier 109 and the resistor 194. A specific method to reduce the resistance through plasma irradiation is not particularly limited, and examples thereof include placing the substrate 110 in plasma of hydrogen gas to introduce hydrogen into the preparatory barrier 191 and the preparatory resistor 195 made from an oxide semiconductor.

Separation Process

FIG. 19 is a cross-sectional view illustrating a state in which a substrate has been cut.

In the present embodiment, the separation line at which the board 110 is cut is located between the common wire 123 and the barrier 109 and between the resistor 194 and the barrier 109.

According to the above-described display panel manufacturing method and display panel, the resistor 194 can be formed in the same process in which the barrier 109 is formed, allowing an end of each of the connecting wires 120 to be given a predetermined resistance without increasing manufacturing steps. With this, it is possible to identify each of the connecting wires 120 in an inspection process. Furthermore, after completion of the inspection, the substrate 110 is cut to remove the resistor 194, meaning that the resistor 194, which is relatively long, does not need to remain on the substrate 110, in the outer peripheral section 182; thus, it is possible to produce the display panel 100 with a narrow frame in which the width of the outer peripheral section 182 is small.

Note that the present invention is not limited to the above-described embodiments. For example, other embodiments that can be realized by arbitrarily combining structural elements described in the present specification or by removing some structural elements may be embodiments of the present invention. Furthermore, modifications obtainable through various changes to the above-described embodiments that can be conceived by a person of ordinary skill in the art without departing from the essence of the present invention, that is, the meaning of the recitations in the claims are included in the present invention.

For example, the barrier forming process may either be performed after the second patterning process or after the third patterning process.

Furthermore, as the barrier forming process, it may be possible to adopt other method than emitting plasma, such as annealing after the formation of a metal film, so long as at least part of the oxide semiconductor can be turned into an electrical conductor.

Furthermore, although the above-described embodiments illustrate top-gated transistors, the present disclosure is applicable to a bottom-gated transistor as well.

### INDUSTRIAL APPLICABILITY

The techniques disclosed herein are widely applicable in the manufacture of a display panel that includes a thin-film transistor using an oxide semiconductor.

1. A display panel manufacturing method of manufacturing a display panel including a substrate, an array of transistors provided in a display region on the substrate, and a plurality of connecting wires provided in an outer peripheral section around the display region and through which a signal for displaying an image is transmitted to the transistors, the display panel manufacturing method comprising:
forming the plurality of connecting wires;
forming a common wire which is electrically connected to the plurality of connecting wires;
forming a first pattern by forming a semiconductor film including an oxide semiconductor and then etching the semiconductor film, the first pattern including a channel and a preparatory barrier which becomes a barrier that electrically connects the connecting wires and the common wire and prevents progression of corrosion;
forming a second pattern by forming a first insulating film in contact with the channel and then etching the first insulating film, the second pattern remaining in a region corresponding to the channel and not remaining on the preparatory barrier;
forming the barrier by reducing resistance of the preparatory barrier, after the forming of a second pattern; and
separating the common wire and the barrier.

2. The display panel manufacturing method according to claim 1,
wherein in the forming of the barrier, plasma is emitted to the preparatory barrier to reduce the resistance of the preparatory barrier and form the barrier.

3. The display panel manufacturing method according to claim 1,
wherein in the forming of the barrier, a resistance-reduction promoting film is formed in contact with the preparatory barrier, and thermally treated upon or after the formation of the resistance-reduction promoting film, to reduce the resistance of the preparatory barrier and form the barrier.

4. The display panel manufacturing method according to claim 1,
wherein in the forming of a first pattern,
the first pattern further includes a preparatory resistor close to an edge of the substrate relative to the preparatory barrier,
in the forming of a second pattern,
the second pattern is a pattern in which the first insulating film does not remain on the preparatory resistor,
the forming of the barrier further includes forming a resistor by reducing resistance of the preparatory resistor, and
in the separating, the resistor and the barrier are separated.

5. A display panel comprising:
a plurality of transistors provided in a matrix in a display region and each having a channel including an oxide semiconductor; and
a plurality of connecting wires provided in an outer peripheral section around the display region and through which a signal for displaying an image is transmitted to the plurality of transistors,
wherein the outer peripheral section includes the oxide semiconductor between the plurality of connecting wires, the oxide semiconductor being formed in a layer in which the channel is formed.

6. The display panel according to claim 5,
wherein the oxide semiconductor has a reduced resistance.
